(19) United States
(12) Patent Application Publication
(10) Pub. No.: US 2014/0375170 A1
(43) Pub. Date: Dec. 25, 2014

(54) ELECTROMECHANICAL TRANSDUCER DEVICE

(71) Applicants: Universal Potsdam, Potsdam (DE); Bayer Intellectual Property GmbH, Monheim (DE)

(72) Inventors: Werner Jenninger, Ahorn-Berolzheim (DE); Reimund Gerhard, Berlin (DE); Werner Wirges, Kleinmachnow (DE); Dmitry Rychkov, Potsdam (DE)

(73) Assignee: Bayer Intellectual Property GmbH, Monheim (DE)

(21) Appl. No.: 14/115,150

(22) PCT Filed: May 4, 2012
(86) PCT No.: PCT/EP2012/058230

§ 371 Date: Feb. 7, 2014

(30) Foreign Application Priority Data
May 6, 2011 (EP) 1165075.0

(51) Int. Cl. H01L 41/08; H01L 41/293; H02N 2/18; H01L 41/314; H01L 41/083; H01L 41/18

(52) U.S. Cl. CPC H01L 41/0825; H01L 41/083; H01L 41/183; H02N 2/18; H01L 41/314; H01L 41/293
USPC 310/339; 310/311; 427/100

(57) ABSTRACT

The invention relates to an electromechanical transducer device (2, 2.1, 2.2, 2.3, 2.4) comprising at least one layer composite (4, 4.1) disposed between a first electrode (6) and at least one second electrode (8). Said layer composite (4, 4.1) comprises a first electro-active layer (10) and at least one second electro-active layer (12), an electret material 14, 14.1) being provided, at least in sections, between the first electro-active layer (10) and the second electro-active layer (12), and the electret material (14) has an electric charge which can be predefined.

The invention relates to an electromechanical transducer device comprising a multilayer composite arranged between a first electrode and at least one second electrode. The invention relates furthermore to an electromechanical transducer system, an actuator device, a generator unit, and a method for producing an electromechanical transducer device.

Plastic composites are employed in many different applications. For example, a corresponding multilayer composite is used as a packaging material, an insulating material, or a construction material. In addition to this conventional purpose, multilayer composites are increasingly employed as active components in generator applications, sensor applications, or actuator applications.

Such multilayer composites generally have at least one electroactive layer such as a dielectric elastomeric layer. In order to obtain an electromechanical transducer device, an electroactive layer can be coated on each side with an electrically conductive layer. The two electrically conductive layers can serve as electrodes. If an electrical signal, for example a voltage, is applied to the electrodes, the dielectric elastomeric layer expands. In particular, an expansion can be generated as a function of a voltage that can lie between a minimum level of 0 V and a maximum level of a breakdown voltage. Conversely, when the multilayer composite is acted upon mechanically, an electrical signal, in particular a voltage, can be tapped at the electrodes as long as an electrical voltage is present at the same time.

A disadvantage of this type of electromechanical transducer device is that voltages in the region of 1000 V need to be applied to the electrodes for an adequate actuator system, in other words in order to achieve a sufficiently great expansion of the electroactive layer. In order to obtain a large amount of energy in the case of generator applications, similarly high voltages need to be applied. However, such high changes in voltage significantly limit the economical and efficient use of electroactive layers or electromechanical transducer devices comprising at least one multilayer composite with an electroactive layer.

The object of the present invention is therefore to provide an electromechanical transducer device that can be operated more economically and in particular more efficiently.

According to a first aspect of the invention, for an electromechanical transducer device comprising at least one multilayer composite arranged between a first electrode and at least one second electrode, the object derived and laid out above is achieved by the multilayer composite having a first electroactive layer and at least one second electroactive layer, and by an electret material being provided between the first electroactive layer and the second electroactive layer at least in some places, the electret material having a predeterminable electric charge.

In contrast to the prior art, according to the teaching of the invention an electromechanical transducer device is provided that can be operated more economically and in particular more efficiently by an electret material with a predeterminable charge being arranged between two electroactive layers.

The electromechanical transducer device comprises at least one multilayer composite, the outer surfaces of which are in each case preferably directly contacted, for example coated, with an electrode. An electrically conductive layer can be arranged on the top of the multilayer composite. Likewise, an electrically conductive layer can be arranged on the underside of the multilayer composite. It should be understood that the top and the underside respectively can be coated with an electrically conductive layer only partly or only in some places. For example, a structured or segmented layer can be formed. An electrically conductive layer can be formed from a material chosen from the group comprising metals, metal alloys, conductive oligomers or polymers, conductive oxides, carbon nanotubes and/or polymers filled with conductive filling material.

The multilayer composite comprises at least two electroactive layers. In particular, an upper electroactive layer and a lower electroactive layer can be provided. The two outer surfaces of the two electroactive layers, which in each case can be contacted with an electrode, can form the outer surfaces of the multilayer composite.

An electret material is provided at least in some places between the first electroactive layer and the second electroactive layer. The electret material can preferably be connected, surface to surface, with the first electroactive layer and/or the second electroactive layer. In other words, the electret material can preferably directly contact the first electroactive layer and the second electroactive layer. In particular, there is no electrically conductive layer provided between the electret material and an electroactive layer.

An electret material has the advantage that electric charges can be (permanently) stored in the electret. The predeterminable electric charge can be generated, for example, by electrically charging the electret material. An electret material can be charged positively or negatively, i.e. can have positive or negative charges. The type and/or magnitude of the charge can be adapted in particular to an application of the electroactive transducer device. For example, the electret layer can have a surface charge density that generates a voltage between the electret layer and an adjacent electrode of 100 to 2000 V.

By arranging an electret material in the multilayer composite which has a permanent electric charge, the advantage is obtained that the voltage which is to be applied to the electrodes in order to obtain a certain degree of expansion is much lower than the prior art. It can in particular be identified that the effect by which there is an approximately quadratic correlation between an electrical field applied at an electroactive layer and the expansion of the electroactive layer can advantageously be used for many different applications. The changes in expansion when there are changes in voltage in the low voltage range are thus small, whereas the changes in expansion when there is a simultaneous change in voltage in the high voltage range are large. It should be understood that the above design also applies correspondingly for a generator application.

According to a first embodiment of the electromechanical transducer device according to the invention, a working point of the electromechanical transducer device can be set as a function of the electric charge of the electret material. As has already been described, there is an approximately quadratic correlation between the expansion of an electroactive layer and the electric field or the voltage present. In principle, the expansion can be set between a minimum value that results when there is no electric field and a maximum value that is determined by the breakdown field strength. The working point can be shifted from zero by introducing an electret material having a predeterminable electric charge. The advantage of shifting the working point is that the change in voltage required for a specific change in expansion can be significantly reduced. The working point can preferably be changed by introducing a permanent charge in such a way that changes in voltage of just 100 V, in particular 10 V, cause a sufficient change in expansion. A sufficient change in expansion, which can depend on the application, is in particular an expansion of at least 0.1 to 35%.

The electret material can in principle be provided in any form. According to an embodiment, the electret material can be formed from electret fibers, electret balls, or an electret layer. An intermediate region of electret fibers or electret balls can thus be provided. An electret layer can preferably be provided because it can be produced easily and has a uniform charge distribution over preferably the whole surface.

According to a further embodiment of the electromechanical transducer device according to the invention, the electret material can advantageously comprise a material chosen from the group comprising polycarbonate, perfluorinated or partially fluorinated polymers and copolymers, polytetrafluoroethylene, fluorinated ethylene propylene, perfluoroalkoxy ethylene, polyester, polyethylene terephthalate, polyimide, polyetherimide, polyether and polyether blends (PPE/PS), polymethyl (meth)acrylate, cyclo olefin polymers, cyclo olefin copolymers and/or polyolefins.

Different materials or layers can be employed as electroactive layers. In particular, the choice of the material can depend on the subsequent purpose. Examples of electroactive layers are piezo layers, electrostrictive polymer layers, liquid-crystalline elastomer layers and the like. According to a preferred embodiment of the electromechanical transducer device of the present invention at least one electroactive layer can be a dielectric elastomer layer. In particular, the dielectric elastomer layer can be a dielectric elastomer film. A dielectric elastomer layer preferably has a relatively high dielectric constant. Moreover, a dielectric elastomer layer preferably has a low mechanical rigidity. These properties result in possible expansion values of up to approximately 300%. A dielectric elastomer layer can be employed in particular for an actuator application. However, dielectric elastomer layers are also suited for sensor or generator applications. The two electroactive layers are preferably formed from the same material.

Furthermore, the dielectric elastomer layer according to a preferred embodiment of the invention can comprise a material that is chosen, for example, from the group comprising polyurethane elastomers, silicone elastomers, rubber elastomers (natural rubber and various copolymers) and/or acrylate elastomers.

The first electroactive layer and the second electroactive layer can preferably be formed from the same material. In particular, the opposing layers can also have the same form and preferably the same dimensions. According to a further embodiment, the first electroactive layer can have a first thickness profile. The second electroactive layer can have a second thickness profile. In particular, the first thickness profile can essentially be the same as the second thickness profile. By virtue of the same thickness profile, an electric field of the same strength can be generated between the first electrode and the electret material and the second electrode and the electret material respectively. This is because the electric field depends directly on the thickness of the intermediate material.

An electroactive layer can expand in at least one direction. In the case of a dielectric elastomer layer, the volume of the layer can remain essentially constant when subjected to an electric field. For example, with a constant volume the thickness can be reduced and the surface area simultaneously increased. In the case of a ferroelectret film, essentially (only) the thickness of the layer can change. However, the ability of the electroactive layers to expand can be limited by further layers that contact the electroactive layers. In order to enable, for example, in the case of a dielectric layer, expansion not only in the thickness direction but also in a longitudinal direction and/or in a transverse direction, it may be necessary for the electret material and/or the electrodes to be designed to be conductive. For example, correspondingly flexible materials can be employed, i.e. materials that have a low rigidity. Examples of flexible materials are elastomers or fluorinated ethylene propylenes filled with electrically conductive filling material.

In order to also be able to employ rigid materials, advantageously according to an embodiment of the electromechanical transducer device according to the invention the at least one electret layer can have a wavelike cross-sectional profile. Alternatively or additionally, at least one electrode can have a wavelike cross-sectional profile. A layer can have a wavelike cross-sectional profile in particular in at least one direction. A wavelike cross-sectional profile has peaks and troughs that can preferably be arranged in an essentially uniform sequence. It should be understood that other sequences can also be provided that can be oriented in particular to the subsequent application. When expansion takes place, the wavelike cross-sectional profile is stretched and the ability to expand in at least one direction thus increased.

According to a further embodiment, the energy source can be connected between the first electrode and the second electrode of the electromechanical transducer device. The energy source can be designed so that it is controllable. In particular, the energy source, for example a voltage source, can be configured so that it generates a voltage difference between the two connected electrodes. Owing to a voltage difference, one of the at least two electroactive layers is expanded more greatly than the other of the at least two electroactive layers. In other words, a bending of the electromechanical transducer device is generated. A bending transducer can be provided simply. For example, a semicircular shape can be generated by a voltage difference in the region of 100 V and less from a flat shape of the transducer device. An asymmetric electromechanical transducer device can be provided. In a further exemplary embodiment, the electromechanical transducer device can be designed as a diaphragm. Tactile feedback can be generated, for example. In this case, the outer electrode is preferably grounded.

In a further embodiment of the transducer device according to the invention, the electromechanical transducer device can be designed in such a way that symmetrical operation of the electromechanical transducer device is possible. In contrast to the previous embodiment, the first and the second electrode can be subjected to the same voltage value. In other words, both electrodes can (at any time) have the same potential. For example, two controllable energy sources can be provided. By applying a low voltage in the region of 100 V, preferably in the region of 10 V, an adequate actuator system can be obtained simply.

In principle, two or more abovedescribed multilayer composites can be cascaded to form a stack. Preferably at least one electrode can be provided between each multilayer composite. Furthermore, in each case one electrode can be provided at least on the outer surfaces of the cascaded multilayer composites.

According to a preferred embodiment, at least one further multilayer composite provided with a further electrode can be provided. The further multilayer composite can have a first electroactive layer and at least one second electroactive layer. For example, the electroactive layers can be dielectric elastomer layers. An electret material can be provided between the first electroactive layer and the second electroactive layer at least in some places or partially. It can contact the two electroactive layers preferably directly. For example, the electret material can be arranged in the form of electret fibers, electret balls and/or an electret layer. The electret material can have a predeterminable electric charge. In particular, the electret material of the further multilayer composite can have the same polarity as the electret material of the first multilayer composite. Furthermore, the amounts of charge of both electret materials can also be essentially the same. The further multilayer composite can be connected to the first electrode or the second electrode. A stack of multiple multilayer composites can be made easily. It is possible to adapt the electromechanical transducer device optimally to a subsequent application.

It should be understood that further multilayer composites and/or intermediate layers can be provided between the at least two multilayer composites.

All the layers of an electroactive transducer device can preferably have a parallel layer profile. In particular, for example the thickness profile of all the electroactive layers can be essentially the same. The profile of a first electret layer can also essentially correspond to the profile of a second electret layer. In a further embodiment of the electromechanical transducer device according to the invention, a first electret layer and at least one further electret layer can have a wavelike cross-sectional profile with peaks and troughs preferably in the same direction, the peaks and troughs of the first electret layer extending parallel to the peaks and troughs of the at least one further electret layer. Then, even when there is a large expansion, the thickness of the elastomer layer in the direction in which the waves extend can remain as uniform as possible.

A further aspect of the present invention is an electromechanical transducer system comprising a first abovedescribed electromechanical transducer device and at least one second abovedescribed transducer device that can be connected electrically to the first electromechanical transducer device.

It should be understood that, according to further variants of the invention, three or more electromechanical transducer devices can be interconnected. The at least one electret material of the first electromechanical transducer device can preferably have an opposite polarity to the at least one electret material of the further electromechanical transducer device. For example, the first electromechanical transducer device can have at least one electret layer that is positively charged. Furthermore, the second electromechanical transducer device can have at least one electret layer that is negatively charged. The amount of charge of the negative charge and the positive charge can preferably be the same.

According to a first embodiment of the electromechanical transducer system according to the invention, at least one electrode of the first electromechanical transducer device can be electrically connectable or connected to at least one first electrode or the second electromechanical transducer device. In particular, all the electrodes of the first electromechanical transducer device can be interconnected with the corresponding electrodes of the second electromechanical transducer device via separate electrical connections. The at least one electret material of the first electromechanical transducer device can preferably have an opposite charge from that of at least one electret material of the second electromechanical transducer device. An equalizing charge for the first or the second electromechanical transducer device can be provided easily by the second or the first electromechanical transducer device, respectively. The reason for this is that the electrodes that are connected in each case have a same amount of voltage with opposite polarity.

For example, an electromechanical transducer device or an electromechanical transducer system can be used in structured pressure sensors for keyboards or touchpads, acceleration sensors, microphones, loudspeakers, ultrasonic transducers for applications in medical technology, marine technology or for materials testing.

A further aspect of the present invention is an actuator device comprising at least one abovedescribed electromechanical transducer device. It should be understood that the actuator device can also have two or more electromechanical transducer devices, for example an abovedescribed electromechanical system. The actuator device can moreover have an energy supply, such as an energy source, and a control system for controlling the energy source or the electromechanical transducer device.

A further aspect of the present invention is a generator device comprising at least one abovedescribed electromechanical transducer device. It should be understood that the generator device can also have two or more electromechanical transducer devices, for example an abovedescribed electromechanical system. The generator device can moreover have an energy supply, such as an energy source, and a control system for controlling the energy source or the electromechanical transducer device.

It should be understood that a sensor device comprising at least one abovedescribed electromechanical transducer device can also be provided.

Yet another aspect of the present invention is a method for producing an electromechanical transducer device, in particular an abovedescribed electromechanical transducer device. The method comprises the following steps:
providing a first electroactive layer,
applying a first electrode to a first surface of the first electroactive layer,
applying an electret material, which has a predeterminable electric charge or can be charged with a predeterminable electric charge, to the second surface of the first electroactive layer,
applying a second electroactive layer to the electret material, and
applying a second electrode to the second electroactive layer.

An electromechanical transducer device that can be operated efficiently can be produced simply. It should be understood here that the steps can take place in any order. According to a first embodiment of the method according to the invention, at least one electroactive layer can be printed at least partially on an electrode. For example, a structured electrode can be imprinted. A printing method can be carried out simply. In particular, an electromechanical transducer device can be mass-produced at a higher production rate.

There are then multiple possibilities for designing and further developing the electromechanical transducer device according to the invention, the electromechanical transducer system according to the invention, the actuator and generator device according to the invention, and the method according to the invention for producing an electromechanical transducer device. Reference is made, on the one hand, to the description of exemplary embodiments in conjunction with the drawings, in which:

FIG. 1 shows a schematic view of a first exemplary embodiment of an electromechanical transducer device according to the present invention;

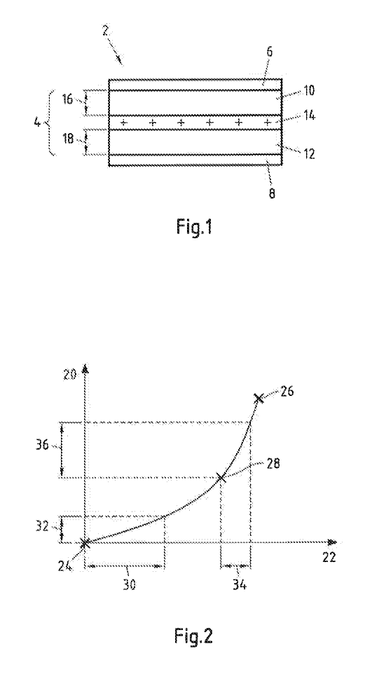

FIG. 2 shows a schematic view of a profile, given by way of example, of an expansion of an electroactive layer as a function of an applied electric field;

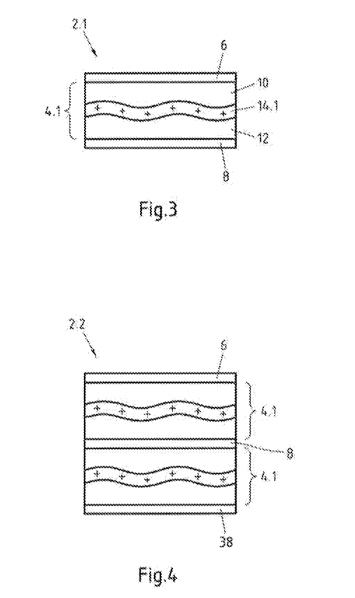

FIG. 3 shows a further schematic view of a further exemplary embodiment of an electromechanical transducer device according to the present invention;

FIG. 4 shows a further schematic view of a further exemplary embodiment of an electromechanical transducer device according to the present invention;

FIG. 5 shows a schematic view of a further exemplary embodiment of an electromechanical transducer device according to the present invention; and

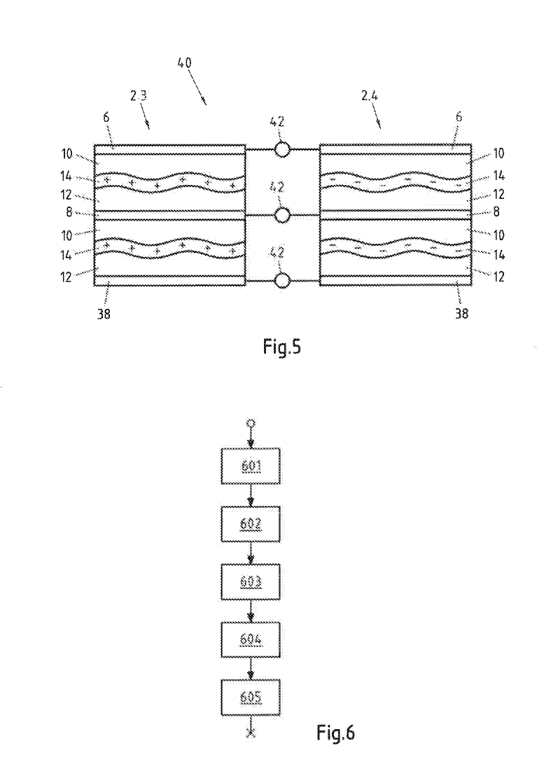

FIG. 6 shows a flow diagram of an exemplary embodiment of a method according to the invention for producing an electromechanical transducer device.

Identical reference numerals are used below for identical elements.

FIG. 1 shows a simplified view, in particular a side view, of an electromechanical transducer device 2 according to the present invention. The electromechanical transducer device 2 comprises a multilayer composite 4. The multilayer composite 4 is arranged between a first electrode 6 and a second electrode 8.

The electrodes 6, 8 can be designed as electrically conductive layers 6, 8. In particular, the electrodes 6, 8 can at least partially directly contact the multilayer composite 4. It should be understood that the underside or the top of the multilayer composite 4 can be coated only partially with an electrically conductive layer 6, 8. For example, at least one structured electrode 6, 8 can be imprinted.

The electrically conductive layer 6, 8 can preferably be formed from a material chosen from the group comprising metals, metal alloys, conductive oligomers or polymers, conductive oxides, carbon nanotubes and/or polymers filled with conductive filling material.

In the present exemplary embodiment the multilayer composite 4 comprises three layers 10, 12 and 14, the layer 14 being arranged between the two layers 10 and 12. In particular, the layer 14 directly contacts both the upper layer 10 and the lower layer 12. In particular, there is no other electrode arranged between the layer 14 and the layer 10 or 12.

The layer 10 is designed as a first electroactive layer 10. The layer 12 is designed as a second electroactive layer 12. A dielectric elastomer layer 10, 12, such as a dielectric elastomer film, can preferably be used as an electroactive layer 10, 12. A dielectric elastomer layer 10, 12 advantageously has a relatively high dielectric constant. Moreover, a dielectric elastomer layer 10, 12 advantageously has a low mechanical rigidity. This results in possible expansion values of up to approximately 300%. A dielectric elastomer layer 10, 12 can in particular be used for an actuator application but also for generator or sensor applications.

It should be understood that other electroactive layers can also be used, such as piezo layers, electrostrictive polymer layers, liquid-crystalline elastomer layers, etc.

The first dielectric layer 10 can have a first thickness 16. The second dielectric layer 12 can have a second thickness 18. The first thickness 16 can essentially be the same as the second thickness 18. It should be understood that a thickness 16, 18 of a layer 10, 12 can be designed so that it differs over the surface area. The two opposite electroactive layers 10 and 12 can preferably have an essentially identical thickness profile.

The layer 14 is an electret layer 14 in the present exemplary embodiment. An electret layer 14 is formed at least partially from an electret material 14. An electret material 14 has the advantage that electric charges can be stored (permanently) in the electret. The electret layer 14 can, for example, be electrically charged before the electret layer 14 is arranged in the multilayer composite 4. It should be understood that the electret layer 14 can be charged only after the electret layer 14 has been arranged in the multilayer composite 4. For example, the electric charging can be carried out by means of direct charging or a corona discharge. By virtue of the charging, the electret layer 14 has a predeterminable permanent charge. For example, a positive charge with a predeterminable value or a negative charge with a predeterminable value can be introduced. In the present exemplary embodiment, the electret layer 14 has positive charges.

It should be understood that, according to other variants of the invention, the electret material 14 can also be provided in other forms, for example in the form of fibers and/or balls which can be arranged between the two electroactive layers 10, 12, preferably evenly distributed over the surface area.

As already described, the electret layer 14 can directly contact the two dielectric elastomer layers 10, 12. For example, the electret layer 14 can be connected on both sides, surface to surface, with the two elastomer layers 10, 12. It should be understood that the electret layer 14 can also be connected only partially to the two elastomer layers 10, 12.

An electret layer 14 which has a predeterminable charge results in an electric field being formed between the first electrode 6 and the electret layer 14. Furthermore, because of the charge of the electret layer 14, an electric field is formed between the second electrode 8 and the electret layer 14. It should be understood that the electrodes 6, 8 can be connected to an equalizing voltage.

Because an electret material 14 that has a predeterminable charge is arranged between two electroactive layers 10, 12, the voltage that needs to be applied for a specific expansion can be significantly reduced, for example in the case of an actuator application. This is explained in detail below with reference to FIG. 2.

FIG. 2 shows a schematic view of a profile, given by way of example, of an expansion 20 of an electroactive layer as a function of an applied electric field 22. The electric field 22 correlates directly with the voltage U applied to the electrodes 6, 8 and the thickness d of an electroactive layer 10, 12 according to the formula E=U/d.

As can be seen in FIG. 2, the curve describes an approximately quadratic profile between an initial value 24 and a final value 26. The initial value 24 is a conventional working point 24 when there is an electric field of 0 V·m⁻¹ and a corresponding expansion of 0. The upper limit value 26 is the breakdown field strength, which depends on the electroactive material used.

In order to effect an expansion of the electroactive material starting from the working point 24, the applied voltage, i.e. the electric field 22 of 0 V·m⁻¹, can be increased by a value 30. This results in an expansion 20 by the value 32. It should be noted that, in spite of a significant increase in the electric field 22 by a value 30, the expansion 20 only grows by a small value 32.

According to the invention, it may in particular be noted that the working point 24 for an electromechanical transducer device 2 can be simply shifted as desired between the lower limit value 24 and the upper limit value 26. The reason for this is that the electromechanical transducer device 2 is already provided with a (permanent) charge. In other words, a bias voltage is already applied. The bias voltage can be selected in a targeted fashion by the electret material 14 being charged appropriately. Consequently, the working point 24 is shifted to the working point 28.

When, starting from the working point 28, the electric field 22 is increased by a value 34, the value 34 being smaller than the value 30, the expansion 20 is altered by a value 36, the value 36 being greater than the value 32. In other words, sufficiently high changes in expansion can be achieved just by a small increase in voltage from, for example, 10 to 100 V.

FIG. 3 shows a further schematic view, in particular a side view, of a further exemplary embodiment of an electromechanical transducer device 2.1 with a multilayer composite 4.1 according to the present invention.

In contrast to the exemplary embodiment according to FIG. 1, the multilayer composite 4.1 according to FIG. 3 has a wavelike electret layer 14.1. A wavelike electret layer 14.1 has a wavelike cross-sectional profile in at least one direction. A wavelike cross-sectional profile has in particular peaks and troughs which are preferably arranged in an essentially uniform sequence. It should be understood that other sequences can also be provided that can be oriented in particular to the subsequent application of the electromechanical transducer device.

A wavelike cross-sectional profile can in particular be used whenever the electret material 14.1 is designed to be relatively rigid, i.e. is only capable of expanding slightly. In order to increase the expandability of such an electret material 14.1, the electret layer 14.1 can have a wavelike cross-sectional profile. When expansion takes place, the wavelike cross-sectional profile is stretched and expansion in at least one direction is thus increased.

An example of a wavelike profile in one direction is when the wavelike profile is formed only in a longitudinal direction in a an electret layer 14.1 that has a thickness direction, a longitudinal direction, and a transverse direction. Another example is the case where this profile develops in a longitudinal and a transverse direction. It should be understood that, according to other variants of the invention, at least one electrode 6, 8 can have a corresponding wavelike cross-sectional profile.

FIG. 4 shows a further exemplary embodiment of an electroactive transducer device 2.2 according to the present invention. The exemplary embodiment shown comprises a first multilayer composite 4.1 and a second multilayer composite 4.1. In other words, two multilayer composites 4.1 and 4.1 are cascaded to form a stack.

The first and the second multilayer composite 4.1 correspond to the multilayer composite 4.1 according to FIG. 3. The multilayer composite 4.1 is arranged between a first and a second electrode 6, 8. In the present exemplary embodiment, an outer layer of the further multilayer composite 4.1 is connected to the lower electrode 8. A further electrode 38 is arranged on the other outer surface.

The electret layer 14.1 of the first multilayer composite 4.1 extends essentially parallel to the electret layer 14.1 of the second multilayer composite 4.2. Furthermore, both electrode layers 14.1 preferably have the same polarity, in the present exemplary embodiment the electret layers 14.1 both being positively charged. Moreover, both electret layers 14.1 can be charged with essentially the same amount of charge.

FIG. 5 shows a schematic view of an exemplary embodiment of an electromechanical transducer system 40. In the present exemplary embodiment, the electromechanical transducer system 40 has a first electromechanical transducer device 2.3 and a second electromechanical transducer device 2.4.

The electromechanical transducer device 2.3 can essentially correspond to the electromechanical transducer device 2.2. The electromechanical transducer device 2.4 can also essentially correspond to the electromechanical transducer device 2.2, in the present exemplary embodiment the polarity of the electret layers 14 of the further electromechanical transducer device 2.4 being opposed to the polarity of the electret layers 14 of the first electromechanical transducer device 2.3. In the present case, the electret layers 14 of the first electromechanical transducer device 2.3 are positively charged and the electret layers 14 of the other electromechanical transducer device 2.4 are negatively charged. The amounts of charge of all the electret layers 14 of the electromechanical transducer system 40 can preferably be essentially the same.

The same amounts of charge but a different polarity means that the respective electrodes 6, 8 and 38 have a different polarity with essentially the same amount of charge. Advantageously, the respective electrodes 6, 8 and 38 can be electrically connected to one another. In this case, the other electromechanical transducer device 2.4 represents the equalizing voltage for the first electromechanical transducer device 2.3, and vice versa.

Furthermore, controllable energy sources 42, in particular controllable voltage sources, can be arranged between the respective electrodes 6, 8 and 38. A desired expansion can be achieved in a targeted fashion by changing the voltage. Sufficient changes in expansion can preferably be achieved by a change in voltage of 100 V, in particular 10 V.

A flow diagram, given by way of example, of an exemplary embodiment of the method according to the invention for producing an electromechanical transducer device, for example an electromechanical transducer device 2 according to FIG. 1, is illustrated in FIG. 6.

In a first step 601, a first electroactive layer 10 can be provided. For example, a dielectric elastomer film can be provided.

In a subsequent step 602, a first electrode 6 can be applied, in the form of an electrically conductive layer 6, to a first surface of the first electroactive layer 10. For example, the electrode 6 can be applied, surface to surface, or in a structured fashion. In particular, the first electroactive layer 10 can be printed accordingly.

Then, in a subsequent step 603, an electret material 14 having a predeterminable electrical charge can be applied to the second surface of the first electroactive layer 10. It can also be provided that electret material 14 can be applied first to an electroactive layer 10, and (only) then is the electret material charged, for example after step 603 or also after step 604 or 605. For example, the electret material 14 can be applied by coating or laminating. In particular, an electret layer 14 can be applied.

In a previous step, the electret material 14 can be charged by tribocharging, electron beam bombardment, or a corona discharge in order to generate a permanent charge. For example, the charging can be carried out using a so-called two-electron corona arrangement. A needle voltage can be at least 20 kV, preferably at least 25 kV, and in particular at least 30 kV. The charging time can be at least 20 s, preferably at least 25 s, and in particular at least 30 s.

It should be understood that the electret material 14 can also be applied first to a surface of the first electroactive layer 10 and only then the first electrode 6. Alternatively, the two steps 602 and 603 can be carried out essentially in parallel.

Furthermore, in a next step 604 a second electroactive layer 12 can be applied to the electret material 14 that has already been applied to the first electroactive layer 10. When an electret layer 14 is provided, the surface lying opposite the surface connected to the first electroactive layer 10 can be coated with the further electroactive layer 12. Also, according to other variants of the invention, an electret layer 14 can be provided and this can be coated on both sides with electroactive layers 10, 12.

Lastly, a second electrode 8 can be applied to the second electroactive layer 12. In other words, the second electrode 8 is applied to the outer surface of the multilayer composite 4. It should also be understood here that the electrode 8 can be applied in advance and, for example, a second electroactive layer 12 provided with an electrode 8 can be provided.

1. An electromechanical transducer device (2, 2.1, 2.2, 2.3, 2.4) comprising:
at least one multilayer composite (4, 4.1) arranged between a first electrode (6) and at least one second electrode (8),
characterized in that
the multilayer composite (4, 4.1) has a first electroactive layer (10) and at least one second electroactive layer (12), and
an electret material (14, 14.1) is provided between the first electroactive layer (10) and the second electroactive layer (12) at least in some places,
the electret material (14) having a predeterminable electric charge.

2. The electromechanical transducer device (2, 2.1, 2.2, 2.3, 2.4) as claimed in claim 1, characterized in that a working point of the electromechanical transducer device (2, 2.1, 2.2, 2.3, 2.4) can be set as a function of the electric charge of the electret material (14, 14.1).

3. The electromechanical transducer device (2, 2.1, 2.2, 2.3, 2.4) as claimed in claim 1 or 2, characterized in that the electret material (14, 14.1) is formed of electret fibers, electret balls and/or an electret layer (14, 14.1).

4. The electromechanical transducer device (2, 2.1, 2.2, 2.3, 2.4) as claimed in one of the preceding claims, characterized in that at least one electroactive layer (10, 12) is a dielectric elastomer layer (10, 12).

5. The electromechanical transducer device (2, 2.1, 2.2, 2.3, 2.4) as claimed in claim 4, characterized in that the dielectric elastomer layer (10, 12) comprises a material that is chosen from the group comprising polyurethane elastomers, silicone elastomers, rubber elastomers (natural rubber and various copolymers) and/or acrylate elastomers.

6. The electromechanical transducer device (2, 2.1, 2.2, 2.3, 2.4) as claimed in one of the preceding claims, characterized in that the electret material (14, 14.1) comprises a material chosen from the group comprising polycarbonate, perfluorinated or partially fluorinated polymers and copolymers, polytetrafluoroethylene, fluorinated ethylene propylene, perfluoroalkoxy ethylene, polyester, polyethylene terephthalate, polyimide, polyetherimide, polyether and polyether blends (PPE/PS), polymethyl (meth)acrylate, cyclo olefin polymers, cyclo olefin copolymers and/or polyolefins.

7. The electromechanical transducer device (2, 2.1, 2.2, 2.3, 2.4) as claimed in one of the preceding claims, characterized in that
the first electroactive layer (10) has a first thickness profile, and
the second electroactive layer (12) has a second thickness profile,
the first thickness profile being essentially the same as the second thickness profile.

8. The electromechanical transducer device (2, 2.1, 2.2, 2.3, 2.4) as claimed in one of the preceding claims, characterized in that
the at least one electret layer (14, 14.1) has a wavelike cross-sectional profile, and/or
at least one electrode (6, 8) has a wavelike cross-sectional profile.

9. The electromechanical transducer device (2, 2.1, 2.2, 2.3, 2.4) as claimed in one of the preceding claims, characterized in that
at least one further multilayer composite (4, 4.1) provided with a further electrode (38) is provided,
the further multilayer composite (4, 4.1) having a first electroactive layer (10) and at least one second electroactive layer (12),
an electret material (14, 14.1) is provided between the first electroactive layer (10) and the second electroactive layer (12) at least in some places or partially,
the electret material having a predeterminable electric charge, and
the multilayer composite (4, 4.1) being connected to the first electrode (6) or the second electrode (8).

10. An electromechanical transducer system (40) comprising a first electromechanical transducer device (2, 2.1, 2.2, 2.3, 2.4) as claimed in one of the preceding claims and at least one second abovedescribed transducer device (2, 2.1, 2.2, 2.3, 2.4) as claimed in one of the preceding claims that can be connected electrically to the first electromechanical transducer device (2, 2.1, 2.2, 2.3, 2.4).

11. The electromechanical transducer system (40) as claimed in claim 10, characterized in that
at least one electrode (6, 8, 38) of the first electromechanical transducer device (2, 2.1, 2.2, 2.3, 2.4) can be electrically connected to at least one first electrode (6, 8, 38) of the second electromechanical transducer device (2, 2.1, 2.2, 2.3, 2.4),
in particular, the at least one electret material (14) of the first electromechanical transducer device (2, 2.1, 2.2, 2.3, 2.4) has an opposite charge from that of at least one electret material (14, 14.1) of the second electromechanical transducer device (2, 2.1, 2.2, 2.3, 2.4).

12. An actuator device comprising at least one electromechanical transducer device (2, 2.1, 2.2, 2.3, 2.4) as claimed in one of the preceding claims 1 to 9.

13. A generator device comprising at least one electromechanical transducer device (2, 2.1, 2.2, 2.3, 2.4) as claimed in one of the preceding claims 1 to 9.

14. A method for producing an electromechanical transducer device (2, 2.1, 2.2, 2.3, 2.4), comprising:
providing a first electroactive layer (10),
applying a first electrode (6) to a first surface of the first electroactive layer (10),
applying an electret material (14), which has a predeterminable electric charge or can be charged with a predeterminable electric charge, to the second surface of the first electroactive layer (10),
applying a second electroactive layer (12) to the electret material (14, 14.1), and
applying a second electrode (8) to the second electroactive layer (12).

15. The method as claimed in claim 12, characterized in that at least one electroactive layer (10, 12) is printed at least partially with an electrode (6, 8, 38).
